(19) United States
(12) Patent Application Publication
(10) Pub. No.: US 2026/0047177 A1
(43) Pub. Date: Feb. 12, 2026

(54) SEMICONDUCTOR DEVICE

(71) Applicant: Mitsubishi Electric Corporation, Tokyo (JP)

(72) Inventor: Tetsuo YAMASHITA, Tokyo (JP)

(73) Assignee: Mitsubishi Electric Corporation, Tokyo (JP)

(21) Appl. No.: 19/204,382

(22) Filed: May 9, 2025

(30) Foreign Application Priority Data
Aug. 7, 2024 (JP) 2024-130866

(51) Int. Cl. H10D 80/20; H01L 23/00; H01L 23/049; H01L 23/373; H01L 25/07

(52) U.S. Cl. CPC H10D 80/251; H01L 23/049; H01L 23/3735; H01L 24/32; H01L 24/48; H01L 24/73; H01L 25/072; H01L 2224/32225; H01L 2224/48137; H01L 2224/48225; H01L 2224/73265; H01L 2924/10272; H01L 2924/13055; H01L 2924/13091

(57) ABSTRACT

A first gate pattern and a first source pattern are linearly formed in parallel to each other along a first edge of an insulating substrate. A second gate pattern is formed in a quadrangular shape in a top view, extending from the first edge side of the insulating substrate to a second edge side facing the first side. A drain pattern is formed to surround at least three edges of the quadrangular shape of the second gate pattern. A second source pattern is formed along an edge other than the first edge of the insulating substrate to surround the drain pattern. First and second semiconductor chip groups are arranged at positions adjacent to the second source pattern. The first and second semiconductor chip groups and the second source pattern are connected via a plurality of first source wires.

### BACKGROUND OF THE INVENTION

### Field of the Invention

The present disclosure relates to a semiconductor device.

### Description of the Background Art

For example, in a semiconductor device described in Japanese Patent Application Laid-Open No. 2018-117054, collector wiring on a ceramic substrate and a plurality of sets of an insulated-gate bipolar transistor (IGBT) chip (corresponding to a semiconductor chip) and a diode chip (corresponding to a semiconductor chip) are bonded to each other by a lower sintered bonding layer over the ceramic substrate. Above the IGBT chip and the diode chip, separate conductive members are connected by an upper sintered bonding layer, emitter wiring on the ceramic substrate, the emitter of the IGBT chip, and the anode of the diode chip are connected by a bonding wire, and the IGBT chip and emitter sense wiring on the ceramic substrate are connected by another bonding wire. The sintered bonding layer includes a lower layer and an upper layer, and these layers are separated from each other, thereby achieving a semiconductor device in which excessive stress is hardly generated in a gate wiring portion and characteristic defects are reduced.

In a semiconductor device in which a gate, a collector (or a drain), and an emitter (or a source) of a semiconductor chip are connected in parallel, a positive feedback circuit is formed from a parasitic capacitance and a floating inductance of the semiconductor chip, and parasitic oscillation may occur. Parasitic oscillation noticeably occurs, especially when the source impedance is large, that is, when a source wire path is long.

In the semiconductor device described in Japanese Patent Application Laid-Open No. 2018-117054, the emitter wiring on the ceramic substrate, the diode chip, and the IGBT chip are arranged in this order, and the distance between the emitter wiring on the ceramic substrate and the IGBT chip is longer, so that the path of the bonding wire connecting the emitter wiring on the ceramic substrate and the IGBT chip (corresponding to the source wire) is longer. Therefore, there is a high possibility that variations in the inductance between the semiconductor chips cause parasitic oscillation between the semiconductor chips, which has been problematic.

### SUMMARY

An object of the present disclosure is to provide a semiconductor device capable of mitigating parasitic oscillation caused by inductance occurring between semiconductor chips.

A semiconductor device according to the present disclosure includes an insulating substrate and first and second semiconductor chip groups. The insulating substrate is formed in a quadrangular shape in a top view, and has a first gate pattern, a second gate pattern, a first source pattern, a second source pattern, and a drain pattern formed on the upper surface. The first and second semiconductor chip groups are mounted on the drain pattern. The first gate pattern and the first source pattern are linearly formed in parallel to each other along the first edge of the insulating substrate. The second gate pattern is formed in a quadrangular shape in the top view, extending from the first edge side of the insulating substrate to the second edge side facing the first edge. The drain pattern is formed to surround at least three sides of the quadrangular shape of the second gate pattern. The second source pattern is formed along a side other than the first side of the insulating substrate to surround the drain pattern. The first and second semiconductor chip groups are arranged at positions adjacent to the second source pattern. The first gate pattern and the second gate pattern are connected via a first gate wire. The second gate pattern and the first and second semiconductor chip groups are connected via a plurality of second gate wires. The first and second semiconductor chip groups and the second source pattern are connected via a plurality of first source wires. The first semiconductor chip group and the second semiconductor chip group are connected via a plurality of second source wires. The first and second semiconductor chip groups and the first source pattern are connected via a plurality of third source wires. The semiconductor chips included in the first and second semiconductor chip groups are connected via the plurality of fourth source wires. A drain main terminal and a source main terminal are connected to the drain pattern and the second source pattern, respectively.

Since the first and second semiconductor chip groups are arranged at positions adjacent to the second source pattern, thereby shortening the lengths of the plurality of first source wires connecting the first and second semiconductor chip groups and the second source pattern. With this configuration, it is possible to reduce variations in inductance occurring between the semiconductor chips included in the first and second semiconductor chip groups, thereby mitigating parasitic oscillation caused by inductance occurring between the semiconductor chips.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematic cross-sectional view for explaining an overall structure of a semiconductor device according to a first preferred embodiment;

FIG. 2 is a top view of an insulating substrate included in the semiconductor device according to the first preferred embodiment;

FIG. 3 is an enlarged top view of first and second semiconductor chip groups mounted on the insulating substrate and a periphery thereof in the first preferred embodiment;

FIG. 4 is a top view of an insulating substrate for explaining the positions of the first and second semiconductor chip groups, the length of a first source wire, and the length of a second source wire in the first preferred embodiment;

FIG. 5 is a top view of an insulating substrate included in a semiconductor device according to a second preferred embodiment;

FIG. 6 is a top view of an insulating substrate included in a semiconductor device according to a third preferred embodiment;

FIG. 7 is a top view of an insulating substrate included in a semiconductor device according to a fourth preferred embodiment;

FIG. 8 is a top view of an insulating substrate included in a semiconductor device according to a fifth preferred embodiment; and

FIG. 9 is a top view of an insulating substrate included in a semiconductor device according to a sixth preferred embodiment.

### DESCRIPTION OF THE PREFERRED EMBODIMENTS

### First Preferred Embodiment

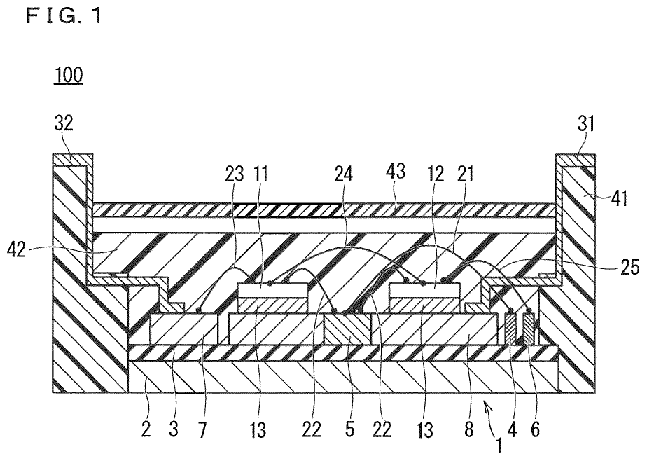

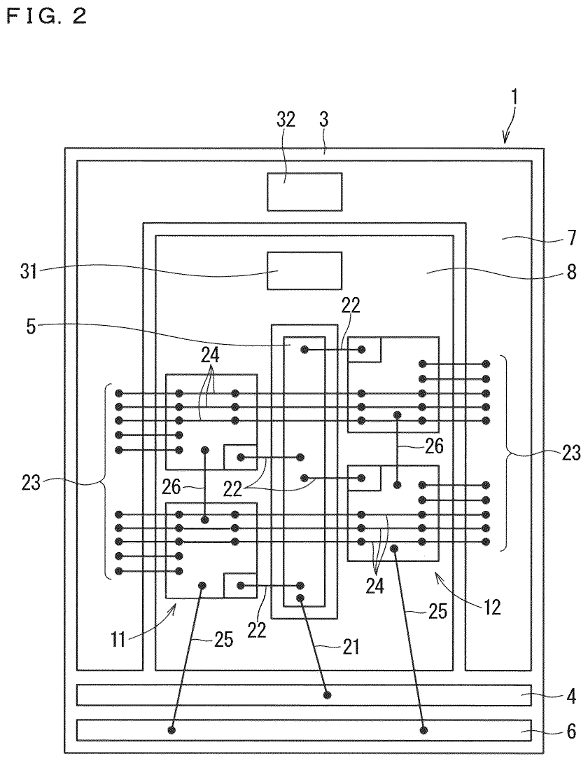

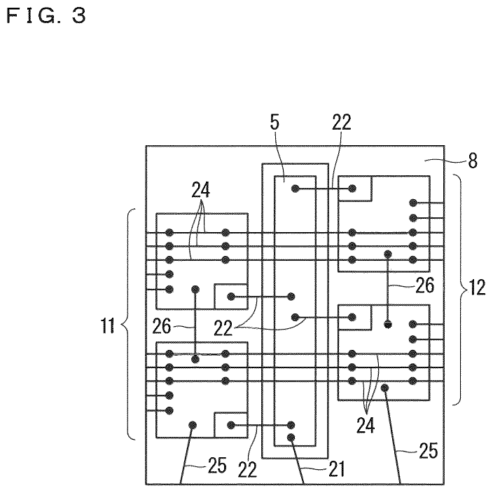

A first preferred embodiment will be described below with reference to the drawings. FIG. 1 is a schematic cross-sectional view for explaining an overall structure of a semiconductor device 100 according to a first preferred embodiment. FIG. 2 is a top view of an insulating substrate 1 included in the semiconductor device 100 according to the first preferred embodiment. FIG. 3 is an enlarged top view of first and second semiconductor chip groups 11, 12 mounted on the insulating substrate 1 and the periphery thereof in the first preferred embodiment.

As illustrated in FIG. 1, the semiconductor device 100 includes an insulating substrate 1, the first semiconductor chip group 11, the second semiconductor chip group 12, a drain main terminal 31, a source main terminal 32, a case 41, a sealing material 42, and a lid 43. Note that FIG. 1 illustrates a schematic cross section to describe the overall structure of the semiconductor device 100, and does not correspond to the top view of FIG. 2.

As illustrated in FIGS. 1 and 2, the insulating substrate 1 is formed in a quadrangular shape in a top view, and includes a base plate 2, an insulating layer 3 formed on the base plate 2, and a circuit pattern formed on the insulating layer 3. As illustrated in FIG. 2, the circuit pattern is formed of metal such as copper, and includes a first gate pattern 4, a second gate pattern 5, a first source pattern 6, a second source pattern 7, and a drain pattern 8.

The first gate pattern 4 and the first source pattern 6 are linearly formed in parallel to each other along the first edge (the lower edge in FIG. 2) of the insulating substrate 1. The first source pattern 6 and the first gate pattern 4 are disposed in this order from the first side of the insulating substrate 1 toward the second edge (the upper edge in FIG. 2) facing the first edge.

The second gate pattern 5 is formed in an elongated quadrangular shape in the top view, extending from the first edge side to the second edge side of the insulating substrate 1. The second gate pattern 5 is disposed closer to the second edge side than the first gate pattern 4.

The drain pattern 8 is formed to surround at least three edges of the quadrangular shape of the second gate pattern 5. More specifically, the drain pattern 8 is formed to surround the four edges of the quadrangular shape of the second gate pattern 5.

The second source pattern 7 is formed along a edge other than the first edge of the insulating substrate 1 to surround the drain pattern 8. More specifically, the second source pattern 7 is formed along the second edge, the third edge, and the fourth edge of the insulating substrate 1 to surround the drain pattern 8. A portion of the second source pattern 7 on the first edge side and a portion of the drain pattern 8 on the first edge side face the first gate pattern 4. Here, the third edge is an edge (left edge in FIG. 2) connecting the first edge and the second edge, and the fourth edge is an edge (right edge in FIG. 2) facing the third edge.

As illustrated in FIG. 1, the first and second semiconductor chip groups 11, 12 are mounted on the drain pattern 8 via a bonding material 13 such as solder. More specifically, as illustrated in FIGS. 2 and 3, the first and second semiconductor chip groups 11, 12 are arranged at positions adjacent to the second source pattern 7 on the drain pattern 8. The first and second semiconductor chip groups 11, 12 face each other across the second gate pattern 5. Specifically, the first semiconductor chip group 11 is disposed on the third edge side, and the second semiconductor chip group 12 is disposed on the fourth edge side.

The first and second semiconductor chip groups 11, 12 each include a plurality of semiconductor chips. The semiconductor chip is formed of a wide-bandgap semiconductor such as SiC, and is, for example, a metal oxide semiconductor field effect transistor (MOSFET). The semiconductor chip may be an insulated gate bipolar transistor (IGBT) or a reverse-conducting IGBT (RC-IGBT) in which an IGBT and a freewheeling diode are formed within one semiconductor substrate.

As illustrated in FIG. 1, the case 41 is formed in a quadrangular frame shape in the top view, and is bonded to the periphery of the insulating substrate 1 with an adhesive (not illustrated). One end sides of the drain main terminal 31 and the source main terminal 32 are fixed to the case 41. The case 41 is filled with a sealing material 42. The sealing material 42 seals the upper surface of the insulating substrate 1, the first and second semiconductor chip groups 11, 12, and the like. The sealing material 42 is, for example, an epoxy resin. The lid 43 that covers the upper surface of the sealing material 42 is attached to the upper portion of the case 41.

Next, connection between the first and second semiconductor chip groups 11, 12 and each circuit pattern will be described.

As illustrated in FIG. 2, the first gate pattern 4 and the second gate pattern 5 are connected via a first gate wire 21. The second gate pattern 5 and the first and second semiconductor chip groups 11, 12 are connected via a plurality of second gate wires 22.

The first and second semiconductor chip groups 11, 12 and the second source pattern 7 are connected via a plurality of first source wires 23. The first semiconductor chip group 11 and the second semiconductor chip group 12 are connected in parallel via a plurality of second source wires 24. The first and second semiconductor chip groups 11, 12 and the first source pattern 6 are connected via a plurality of third source wires 25. The semiconductor chips included in the first and second semiconductor chip groups 11, 12 are connected via a plurality of fourth source wires 26.

The drain main terminal 31 and the source main terminal 32 are connected to the drain pattern 8 and the second source pattern 7, respectively, via a bonding material (not illustrated) such as solder, a wire (not illustrated), or the like.

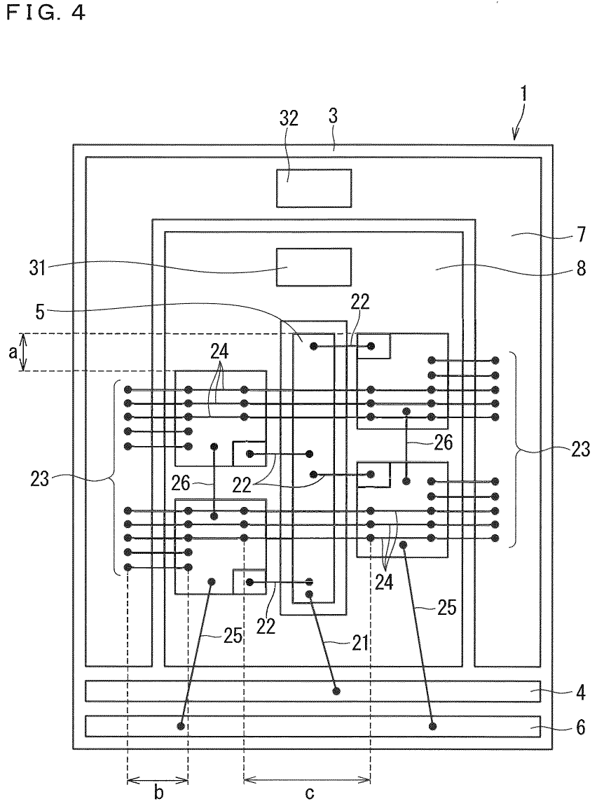

Next, the positional relationship between the first and second semiconductor chip groups 11, 12 and the length of the source wire connected thereto will be described. FIG. 4 is a top view of the insulating substrate 1 for explaining the positions of the first and second semiconductor chip groups 11, 12, the length of the first source wire 23, and the length of the second source wire 24 in the first preferred embodiment.

As illustrated in FIG. 4, the semiconductor chips included in the first semiconductor chip group 11 and the semiconductor chips included in the second semiconductor chip group 12 have the same structure. The first semiconductor chip group 11 is disposed rotated 180° laterally with respect to the second semiconductor chip group 12. In other words, the first semiconductor chip group 11 is disposed in the opposite direction laterally with respect to the second semiconductor chip group 12. Furthermore, the first semiconductor chip group 11 is disposed with a shift from the second semiconductor chip group 12 by a length a corresponding to 20% of the length of the third edge in a direction parallel to the third edge of the insulating substrate 1. In a case where the first semiconductor chip group 11 is not disposed with a shift from the second semiconductor chip group 12, the length of the plurality of second source wires 24 is longer. However, since the first semiconductor chip group 11 is disposed with a shift, the plurality of second source wires 24 can be connected in the shortest time.

The lengths b of the plurality of first source wires 23 are equal or, considering manufacturing variations, have a deviation within ±3%. The lengths c of the plurality of second source wires 24 are equal or, considering manufacturing variations, have a deviation within ±3%.

As described above, in the first preferred embodiment, the semiconductor device 100 includes the insulating substrate 1 formed in a quadrangular shape in the top view and including the first gate pattern 4, the second gate pattern 5, the first source pattern 6, the second source pattern 7, and the drain pattern 8 formed on the upper surface, and the first and second semiconductor chip groups 11, 12 mounted on the drain pattern 8. The first gate pattern 4 and the first source pattern 6 are linearly formed in parallel to each other along the first edge of the insulating substrate 1. The second gate pattern 5 extends from the first edge side of the insulating substrate 1 to the second edge side facing the first edge, and is formed in a quadrangular shape in the top view. The drain pattern 8 is formed to surround at least three edges of the quadrangular shape of the second gate pattern 5. The second source pattern 7 is formed along an edge other than the first edge of the insulating substrate 1 to surround the drain pattern 8. The first and second semiconductor chip groups 11, 12 are arranged at positions adjacent to the second source pattern 7. The first gate pattern 4 and the second gate pattern 5 are connected via the first gate wire 21. The second gate pattern 5 and the first and second semiconductor chip groups 11, 12 are connected via a plurality of second gate wires 22. The first and second semiconductor chip groups 11, 12 and the second source pattern 7 are connected via a plurality of first source wires 23. The first semiconductor chip group 11 and the second semiconductor chip group 12 are connected via the plurality of second source wires 24. The first and second semiconductor chip groups 11, 12 and the first source pattern 6 are connected via a plurality of third source wires 25. The semiconductor chips included in the first and second semiconductor chip groups 11, 12 are connected via a plurality of fourth source wires 26. A drain main terminal 31 and a source main terminal 32 are connected to the drain pattern 8 and the second source pattern 7, respectively.

Specifically, the drain pattern 8 is formed to surround the four edges of the quadrangular shape of the second gate pattern 5.

Therefore, the first and second semiconductor chip groups 11, 12 are arranged at positions adjacent to the second source pattern 7, thereby shortening the lengths of the plurality of first source wires 23 connecting the first and second semiconductor chip groups 11, 12 and the second source pattern 7. With this configuration, it is possible to reduce variations in inductance occurring between the semiconductor chips included in the first and second semiconductor chip groups 11, 12, thereby mitigating parasitic oscillation caused by inductance occurring between the semiconductor chips.

When the plurality of second gate wires 22 are used, and the second gate pattern 5 is connected to the first and second semiconductor chip groups 11, 12 via the two second gate wires 22, respectively, induction is less likely to be received than when stitching is performed with a single wire. This can enhance the effect as an oscillation countermeasure.

The first semiconductor chip group 11 is disposed with a shift from the second semiconductor chip group 12 by a length corresponding to 20% of the length of the third edge, which connects the first edge and the second edge of the insulating substrate 1, in a direction parallel to the third edge. Therefore, the plurality of second source wires 24 can be shortened compared to a case where the first semiconductor chip group 11 is not disposed with a shift from the second semiconductor chip group 12.

The lengths of the plurality of first source wires 23 are equal or have a deviation within ±3%. Similarly, the lengths of the plurality of second source wires 24 are equal or have a deviation within ±3%. Therefore, it is possible to further reduce variations in inductance occurring between the semiconductor chips, thus further mitigating parasitic oscillation caused by inductance occurring between the semiconductor chips.

Each of the semiconductor chips included in the first and second semiconductor chip groups 11, 12 are formed of a wide-bandgap semiconductor. Since the semiconductor chip formed of the wide-bandgap semiconductor is driven at a high speed, variation in inductance between the semiconductor chips is likely to occur. However, since the variation in inductance can be reduced by the configuration of the semiconductor device 100 according to the first preferred embodiment, an excellent effect can be exhibited in this case.

### Second Preferred Embodiment

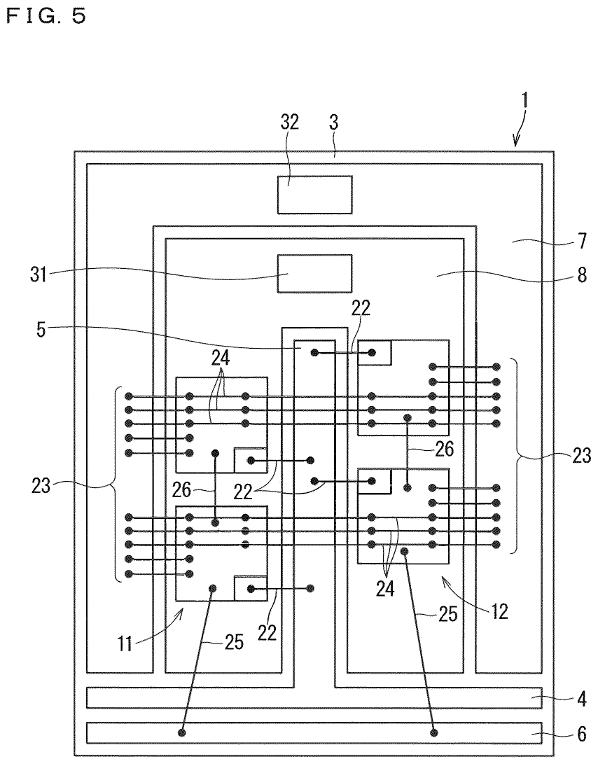

Next, a second preferred embodiment will be described. FIG. 5 is a top view of an insulating substrate 1 included in a semiconductor device 100 according to the second preferred embodiment. In the second preferred embodiment, the same components as those described in the first preferred embodiment are denoted by the same reference numerals, and description thereof is omitted.

As illustrated in FIG. 5, in the second preferred embodiment, the first gate pattern 4 and the second gate pattern 5 are integrally formed instead of the first gate wire 21. That is, first gate wire 21 is not used. The drain pattern 8 is formed to surround three edges of the quadrangular shape of the second gate pattern 5.

As described above, in the second preferred embodiment, effects similar to those of the first preferred embodiment can be obtained. In addition, since the first gate wire 21 can be eliminated, the manufacturing process of the semiconductor device 100 can contribute to a reduction in man-hours.

### Third Preferred Embodiment

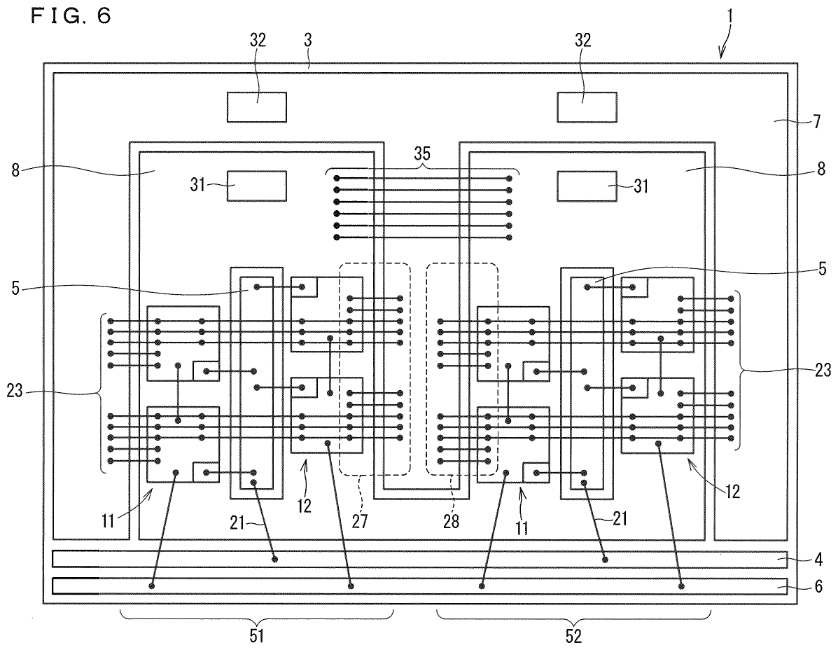

Next, a third preferred embodiment will be described. FIG. 6 is a top view of an insulating substrate 1 included in a semiconductor device 100 according to the third preferred embodiment. In the third preferred embodiment, the same components as those described in the first and second preferred embodiments are denoted by the same reference numerals, and description thereof is omitted.

As illustrated in FIG. 6, in the third preferred embodiment, two configurations of the first preferred embodiment are arranged in parallel. Specifically, when the second gate pattern 5 and the drain pattern 8 are formed as one block, the insulating substrate 1 has two blocks 51, 52 formed to be adjacent to each other. The two blocks 51, 52 are arranged in parallel in a direction parallel to the first edge. The first and second semiconductor chip groups 11, 12 are mounted on the two blocks 51, 52. The second source pattern 7 is formed along a edge other than the first edge to surround the two blocks 51, 52, and extends to a region between the two blocks 51, 52.

The semiconductor chip groups 11, 12 adjacent to the region on both sides among the first and second semiconductor chip groups 11, 12, and a portion extending to the region in the second source pattern 7, are connected, respectively, via a plurality of sixth source wires 28 and a plurality of fifth source wires 27, instead of the plurality of first source wires 23. Therefore, the plurality of first source wires 23 connect the second source pattern 7 and the semiconductor chip groups 11, 12 that are not adjacent to the region among the first and second semiconductor chip groups 11, 12.

As described above, in the third preferred embodiment, not only effects similar to those of the first preferred embodiment can be obtained, but also a large capacity can be achieved.

### Fourth Preferred Embodiment

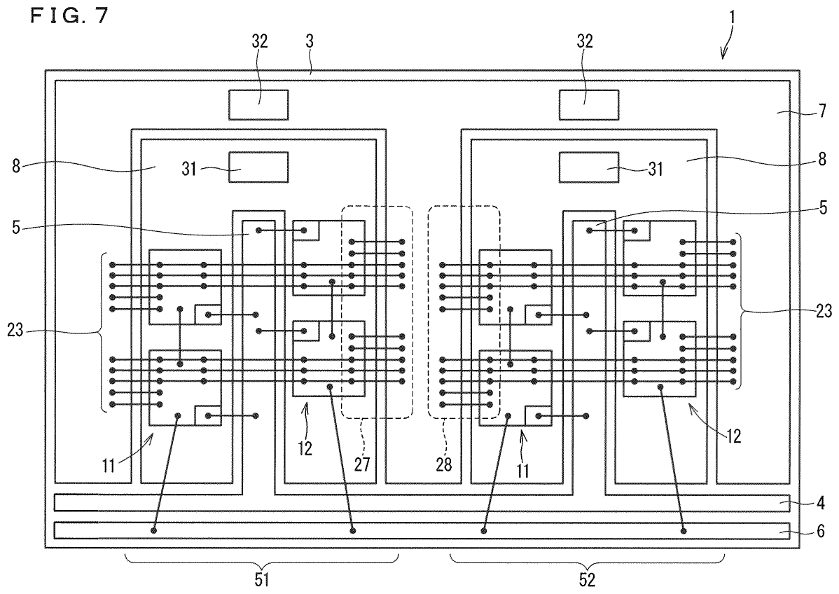

Next, a fourth preferred embodiment will be described. FIG. 7 is a top view of an insulating substrate 1 included in a semiconductor device 100 according to the fourth preferred embodiment. In the fourth preferred embodiment, the same components as those described in the first to third preferred embodiments are denoted by the same reference numerals, and description thereof is omitted.

As illustrated in FIG. 7, in the fourth preferred embodiment, two blocks 51, 52 in the third preferred embodiment are replaced with the configuration of the second preferred embodiment. Specifically, in the two blocks 51, 52, the first gate pattern 4 and the second gate pattern 5 are integrally formed instead of the first gate wire 21. The drain pattern 8 is formed to surround three edges of the quadrangular shape of the second gate pattern 5.

As described above, in the fourth preferred embodiment, effects similar to those of the third preferred embodiment can be obtained. In addition, since the first gate wire 21 can be eliminated, the manufacturing process of the semiconductor device 100 can contribute to a reduction in man-hours.

### Fifth Preferred Embodiment

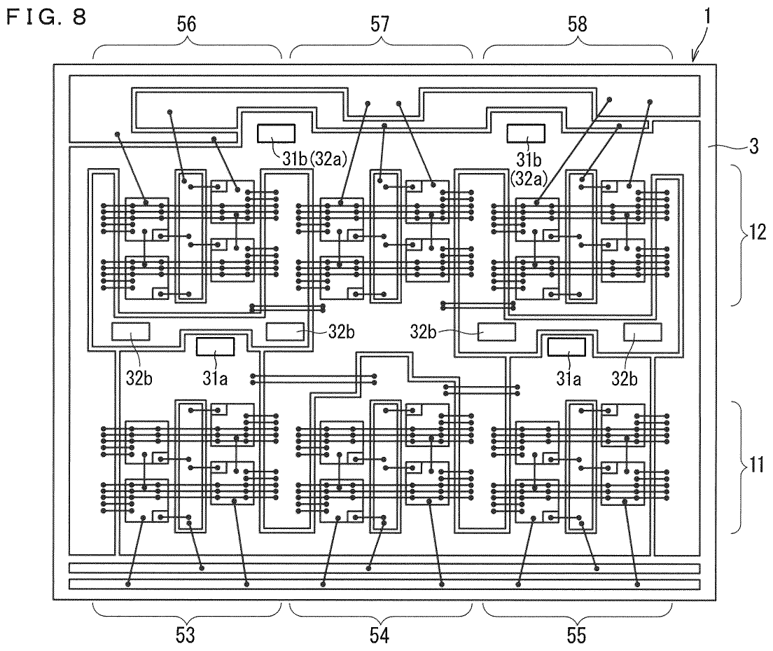

Next, a fifth preferred embodiment will be described. FIG. 8 is a top view of an insulating substrate 1 included in a semiconductor device 100 according to the fifth preferred embodiment. In the fifth preferred embodiment, the same components as those described in the first to fourth preferred embodiments are denoted by the same reference numerals, and description thereof is omitted.

As illustrated in FIG. 8, in the fifth preferred embodiment, when the second gate pattern 5 and the drain pattern 8 are formed as one block, the insulating substrate 1 includes three first blocks 53, 54, 55 formed adjacent to each other on the first edge side and three second blocks 56, 57, 58 formed adjacent to each other on the second edge side. The three first blocks 53, 54, 55 and the three second blocks 56, 57, 58 face each other.

The first semiconductor chip group 11 is mounted on each of the three first blocks 53, 54, 55, and the second semiconductor chip group 12 is mounted on each of the three second blocks 56, 57, 58. Therefore, the first and second semiconductor chip groups 11, 12 also face each other, and the first and second semiconductor chip groups 11, 12 facing each other are connected in series.

A first drain main terminal 31a is connected to the three first blocks 53, 54, 55. A second drain main terminal 31b serving as a first source main terminal 32a and a second source main terminal 32b are connected to the three second blocks 56, 57, 58.

As described above, in the fifth preferred embodiment, a half-bridge circuit can be configured. In addition, by arranging the semiconductor devices 100 according to the fifth preferred embodiment in parallel, a multiphase inverter can be easily configured.

### Sixth Preferred Embodiment

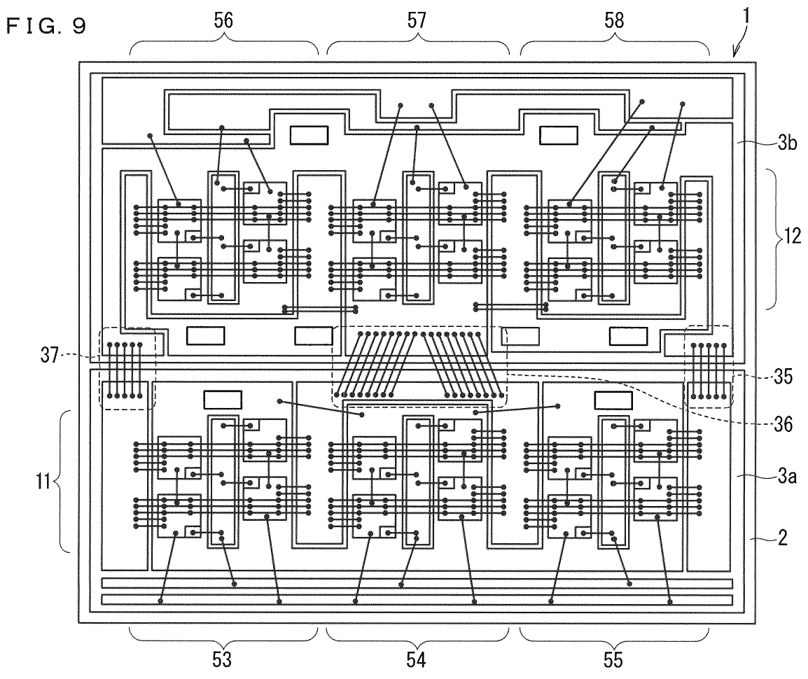

Next, a sixth preferred embodiment will be described. FIG. 9 is a top view of an insulating substrate 1 included in a semiconductor device 100 according to the sixth preferred embodiment. In the sixth preferred embodiment, the same components as those described in the first to fifth preferred embodiments are denoted by the same reference numerals, and description thereof is omitted.

As illustrated in FIG. 9, in the sixth preferred embodiment, the insulating substrate 1 includes a first ceramic substrate 3a and a second ceramic substrate 3b instead of the insulating layer 3. In other words, the insulating layer 3 is divided into two ceramic substrates 3a, 3b.

The three first blocks 53, 54, 55 are formed on the first ceramic substrate 3a, and the three second blocks 56, 57, 58 are formed on the second ceramic substrate 3b. The first ceramic substrate 3a and the second ceramic substrate 3b are connected by a plurality of first drain wires 35, a plurality of second drain wires 36, and a plurality of third drain wires 37.

As described above, in the sixth preferred embodiment, since the insulating layer 3 of the insulating substrate 1 is divided into the two ceramic substrates 3a, 3b, the heat dissipation of the insulating substrate 1 is improved, which can contribute to the improvement of the power cycle life.

Note that the embodiments can be freely combined, and the embodiments can be appropriately modified or omitted.

Hereinafter, various aspects of the present disclosure will be collectively described as appendixes.

### APPENDIX 1

A semiconductor device comprising:
an insulating substrate formed in a quadrangular shape in a top view and having a first gate pattern, a second gate pattern, a first source pattern, a second source pattern, and a drain pattern formed on an upper surface; and
first and second semiconductor chip groups mounted on the drain pattern,
wherein
the first gate pattern and the first source pattern are linearly formed in parallel to each other along a first edge of the insulating substrate,
the second gate pattern is formed in a quadrangular shape in the top view, extending from the first edge side of the insulating substrate to a second edge side facing the first edge,
the drain pattern is formed to surround at least three sides of the quadrangular shape of the second gate pattern,
the second source pattern is formed along an edge other than the first edge of the insulating substrate to surround the drain pattern,
the first and second semiconductor chip groups are arranged at positions adjacent to the second source pattern,
the first gate pattern and the second gate pattern are connected via a first gate wire,
the second gate pattern and the first and second semiconductor chip groups are connected via a plurality of second gate wires,
the first and second semiconductor chip groups and the second source pattern are connected via a plurality of first source wires,
the first semiconductor chip group and the second semiconductor chip group are connected via a plurality of second source wires,
the first and second semiconductor chip groups and the first source pattern are connected via a plurality of third source wires,
the semiconductor chips included in the first and second semiconductor chip groups are connected via a plurality of fourth source wires, and
a drain main terminal and a source main terminal are connected to the drain pattern and the second source pattern, respectively.

### APPENDIX 2

The semiconductor device according to Appendix 1, wherein the drain pattern is formed to surround four sides of the quadrangular shape of the second gate pattern.

### APPENDIX 3

The semiconductor device according to Appendix 1, wherein
the first gate pattern and the second gate pattern are integrally formed in place of the first gate wire, and
the drain pattern is formed to surround three edges of the quadrangular shape of the second gate pattern.

### APPENDIX 4

The semiconductor device according to any one of Appendixes 1 to 3, wherein the first semiconductor chip group is disposed with a shift from the second semiconductor chip group by a length corresponding to 20% of a length of a third edge in a direction parallel to the third edge, the third edge connecting the first edge and the second edge of the insulating substrate.

### APPENDIX 5

The semiconductor device according to any one of Appendixes 1 to 4, wherein lengths of the plurality of first source wires are equal or have a deviation within ±3%.

### APPENDIX 6

The semiconductor device according to any one of Appendixes 1 to 5, wherein lengths of the plurality of second source wires are equal or have a deviation within ±3%.

### APPENDIX 7

The semiconductor device according to Appendix 1, wherein
the second gate pattern and the drain pattern are formed as one of blocks,
the insulating substrate includes two of the blocks formed to be adjacent to each other,
the second source pattern extends to a region between two of the blocks, and
semiconductor chip groups adjacent to the region on both sides among the first and second semiconductor chip groups, and a portion extending to the region in the second source pattern, are connected, respectively, via a plurality of sixth source wires and a plurality of fifth source wires.

### APPENDIX 8

The semiconductor device according to Appendix 7, wherein
the first gate pattern and the second gate pattern are integrally formed in place of the first gate wire, and
the drain pattern is formed to surround three edges of the quadrangular shape of the second gate pattern.

### APPENDIX 9

The semiconductor device according to Appendix 1, wherein
the second gate pattern and the drain pattern are formed as one of blocks,
the insulating substrate includes three first blocks formed adjacent to each other on the first edge side and three second blocks formed adjacent to each other on the second edge side,
the first semiconductor chip group is mounted on each of the three first blocks and the second semiconductor chip group is mounted on each of the three second blocks,
the drain main terminal includes first and second drain main terminals,
the source main terminal includes first and second source main terminals,
the first drain main terminal is connected to the three first blocks, and
the second drain main terminal serving as the first source main terminal and the second source main terminal are connected to the three second blocks.

### APPENDIX 10

The semiconductor device according to Appendix 9, wherein
the insulating substrate includes a first ceramic substrate and a second ceramic substrate,
three of the first blocks are formed on the first ceramic substrates, and three of the second blocks are formed on the second ceramic substrates, and
the first ceramic substrate and the second ceramic substrate are connected by a first drain wire, a second drain wire, and a third drain wire.

### APPENDIX 11

The semiconductor device according to any one of Appendixes 1 to 10, wherein each of the semiconductor chips included in the first and second semiconductor chip groups is formed of a wide-bandgap semiconductor.

While the disclosure has been shown and described in detail, the foregoing description is in all aspects illustrative and not restrictive. It is therefore understood that numerous modifications and variations can be devised.

What is claimed is:

1. A semiconductor device comprising:
an insulating substrate formed in a quadrangular shape in a top view and having a first gate pattern, a second gate pattern, a first source pattern, a second source pattern, and a drain pattern formed on an upper surface; and
first and second semiconductor chip groups mounted on the drain pattern,
wherein
the first gate pattern and the first source pattern are linearly formed in parallel to each other along a first edge of the insulating substrate,
the second gate pattern is formed in a quadrangular shape in the top view, extending from the first edge side of the insulating substrate to a second edge side facing the first edge,
the drain pattern is formed to surround at least three edges of the quadrangular shape of the second gate pattern,
the second source pattern is formed along an edge other than the first edge of the insulating substrate to surround the drain pattern,
the first and second semiconductor chip groups are arranged at positions adjacent to the second source pattern,
the first gate pattern and the second gate pattern are connected via a first gate wire,
the second gate pattern and the first and second semiconductor chip groups are connected via a plurality of second gate wires,
the first and second semiconductor chip groups and the second source pattern are connected via a plurality of first source wires,
the first semiconductor chip group and the second semiconductor chip group are connected via a plurality of second source wires,
the first and second semiconductor chip groups and the first source pattern are connected via a plurality of third source wires,
the semiconductor chips included in the first and second semiconductor chip groups are connected via a plurality of fourth source wires, and
a drain main terminal and a source main terminal are connected to the drain pattern and the second source pattern, respectively.

2. The semiconductor device according to claim 1, wherein the drain pattern is formed to surround four sides of the quadrangular shape of the second gate pattern.

3. The semiconductor device according to claim 1, wherein
the first gate pattern and the second gate pattern are integrally formed in place of the first gate wire, and
the drain pattern is formed to surround three edges of the quadrangular shape of the second gate pattern.

4. The semiconductor device according to claim 1, wherein the first semiconductor chip group is disposed with a shift from the second semiconductor chip group by a length corresponding to 20% of a length of a third edge in a direction parallel to the third edge, the third edge connecting the first edge and the second edge of the insulating substrate.

5. The semiconductor device according to claim 1, wherein lengths of the plurality of first source wires are equal or have a deviation within ±3%.

6. The semiconductor device according to claim 1, wherein lengths of the plurality of second source wires are equal or have a deviation within ±3%.

7. The semiconductor device according to claim 1, wherein
the second gate pattern and the drain pattern are formed as one of blocks,
the insulating substrate includes two of the blocks formed to be adjacent to each other,
the second source pattern extends to a region between two of the blocks, and
semiconductor chip groups adjacent to the region on both sides among the first and second semiconductor chip groups, and a portion extending to the region in the second source pattern, are connected, respectively, via a plurality of sixth source wires and a plurality of fifth source wires.

8. The semiconductor device according to claim 7, wherein
the first gate pattern and the second gate pattern are integrally formed in place of the first gate wire, and
the drain pattern is formed to surround three edges of the quadrangular shape of the second gate pattern.

9. The semiconductor device according to claim 1, wherein
the second gate pattern and the drain pattern are formed as one of blocks,
the insulating substrate includes three first blocks formed adjacent to each other on the first edge side and three second blocks formed adjacent to each other on the second edge side,
the first semiconductor chip group is mounted on each of the three first blocks and the second semiconductor chip group is mounted on each of the three second blocks,
the drain main terminal includes first and second drain main terminals,
the source main terminal includes first and second source main terminals,
the first drain main terminal is connected to the three first blocks, and
the second drain main terminal serving as the first source main terminal and the second source main terminal are connected to the three second blocks.

10. The semiconductor device according to claim 9, wherein
the insulating substrate includes a first ceramic substrate and a second ceramic substrate,
three of the first blocks are formed on the first ceramic substrates, and three of the second blocks are formed on the second ceramic substrates, and
the first ceramic substrate and the second ceramic substrate are connected by a first drain wire, a second drain wire, and a third drain wire.

11. The semiconductor device according to claim 1, wherein each of the semiconductor chips included in the first and second semiconductor chip groups is formed of a wide-bandgap semiconductor.
